(19) United States
(12) Patent Application Publication
(10) Pub. No.: US 2024/0405020 A1
(43) Pub. Date: Dec. 5, 2024

(54) SEMICONDUCTOR DEVICES

(71) Applicant: Taiwan Semiconductor Manufacturing Company, Ltd., Hsinchu (TW)

(72) Inventor: Jhon Jhy Liaw, Hsinchu County (TW)

(73) Assignee: Taiwan Semiconductor Manufacturing Company, Ltd., Hsinchu (TW)

(21) Appl. No.: 18/327,082

(22) Filed: Jun. 1, 2023

(51) Int. Cl. H01L 27/092; H01L 23/535; H01L 29/06; H01L 29/423; H01L 29/775

(52) U.S. Cl. CPC H01L 27/092; H01L 23/535; H01L 29/0673; H01L 29/42392; H01L 29/775

(57) ABSTRACT

A semiconductor device includes a first region and a second region disposed adjacent to each other and having a boundary therebetween. The first region includes a first active region, a second active region and a third active region extending in a first direction and having different widths measured along a second direction. The first region includes a first gate electrode, a second gate electrode and a third gate electrode extending in the second direction and disposed across the first active region, the second active region and the third active region respectively. From a top view, the first active region has a first edge and a second edge opposite to each other, the first edge of the first active region is aligned with an edge of the second active region, and the second edge of the first active region is aligned with an edge of the third active region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 3 are top views of a layout of a semiconductor device construed at various fabrication stages in accordance with some embodiments.

FIG. 4 to FIG. 9 are cross-sectional views taken along lines I-I′, II-II′, III-III′, IV-IV′, V-V′ and VI-VI′ of FIG. 3 in accordance with some embodiments.

FIG. 10 to FIG. 12 are top views of a layout of a semiconductor device construed at various fabrication stages in accordance with some embodiments.

FIG. 13 to FIG. 14 are top views of a layout of a semiconductor device construed at various fabrication stages in accordance with some embodiments.

FIG. 15 is a top view of a layout of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

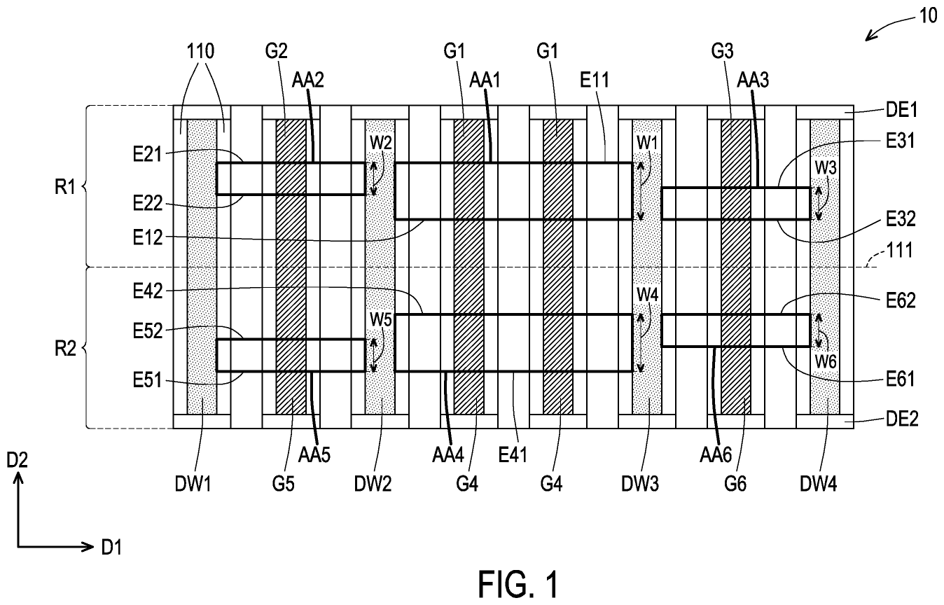

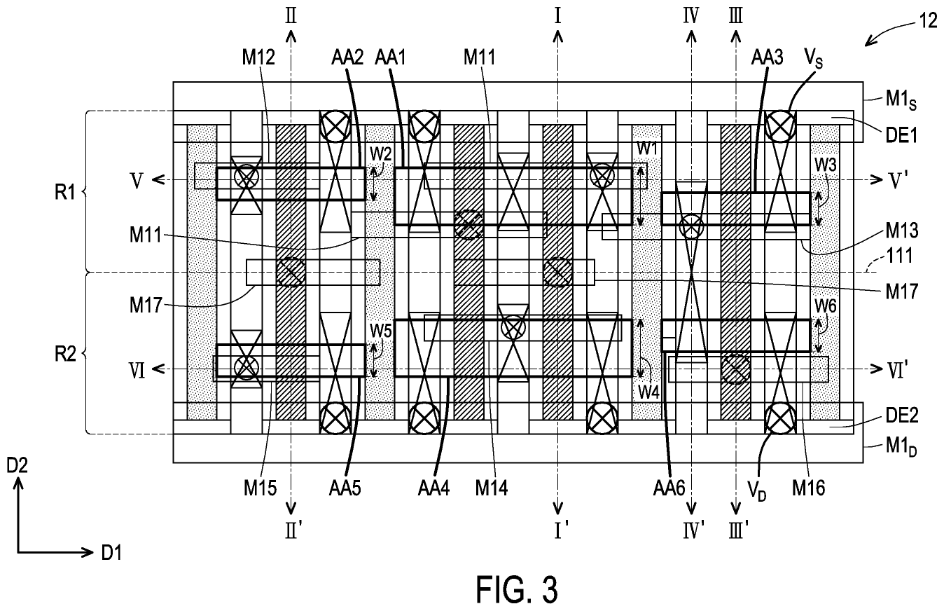

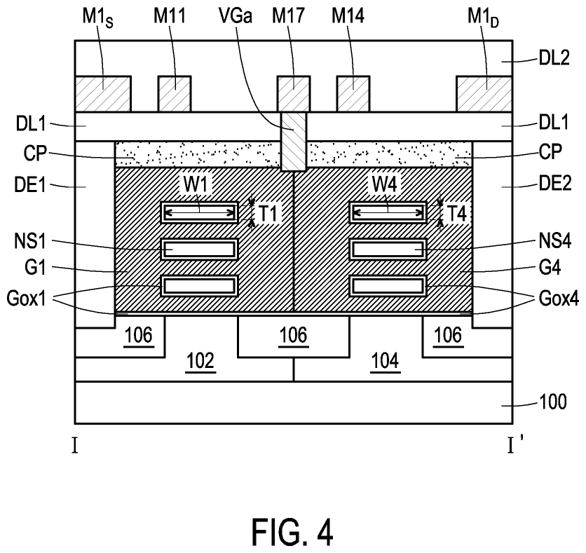

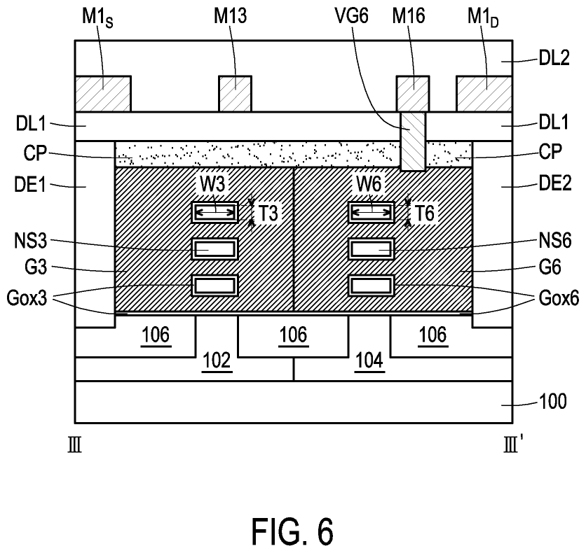

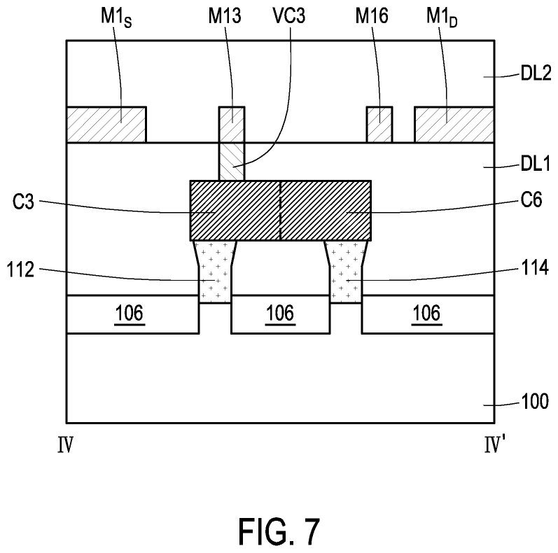

FIG. 1 to FIG. 3 are top views of a layout of a semiconductor device construed at various fabrication stages in accordance with some embodiments. In some embodiments, the layout is stored in a computer or a non-transitory computer-readable medium. FIG. 4 to FIG. 9 are cross-sectional views taken along lines I-I′, II-II′, III-III′, IV-IV′, V-V′ and VI-VI′ of FIG. 3 in accordance with some embodiments.

Referring to FIG. 1 and FIG. 4 to FIG. 9, a semiconductor device 10 includes a substrate 100. The substrate includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof.

The semiconductor device 10 includes a first region R1 and a second region R2 adjacent to each other and having a boundary 111 therebetween. The first region R1 and the second region R2 are both device regions. The devices may include active components and/or passive components. In some embodiments, each device includes a gate-all-around (GAA) device, but the disclosure is not limited thereto. In other embodiments, each device may include a fin-type field effect transistor (FinFET) device, a planar device such as a metal oxide semiconductor field effect transistor (MOSFET) device, or the like. In some embodiments, the first region R1 is an N-type device region, and the second region R2 is a P-type device region. However, the disclosure is not limited thereto. In other embodiments, the first region R1 is a P-type device region, and the second region R2 is an N-type device region. In some embodiments, the devices in the first region R1 and the second region R2 constitute a complementary metal oxide semiconductor (CMOS) transistor, and the boundary 111 between the first region R1 and the second region R2 may be referred to as an N—P boundary.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As shown in FIG. 1, the semiconductor device 10 further includes active regions AA1, AA2 and AA3 with different widths in the first region R1 and active regions AA4, AA5 and AA6 with different widths in the second region R2. The active regions AA1, AA2, AA3, AA4, AA5 and AA6 extend in a first direction D1. The first direction D1 may be a X-direction. In some embodiments, the active region AA1 is disposed between the active regions AA2 and AA3, and the active region AA4 is disposed between the active regions AA5 and AA6. However, the present disclosure is not limited thereto. The locations of active regions can be adjusted as needed. For example, the active region AA2 may be disposed between the active regions AA1 and AA3, and the active region AA5 may be disposed between the active regions AA4 and AA6.

From another point of view, the active regions AA1, AA2 and AA3 in the first region R1 may be regarded as active regions arranged in a first row, while the active regions AA4, AA5 and AA6 in the second region R2 may be regarded as active regions arranged in a second row. The active regions AA1 and AA4 in different regions R1 and R2 may be regarded as active regions arranged in a first column, the active regions AA2 and AA5 in different regions R1 and R2 may be regarded as active regions arranged in a second column, and the active regions AA3 and AA6 in different regions R1 and R2 may be regarded as active regions arranged in a third column.

In some embodiments, the widths of the active regions AA1, AA2, AA3, AA4, AA5 and AA6 are defined as widths measured along a second direction D2 different from the first direction D1. The second direction D2 may be a Y-direction.

In some embodiments, the active region AA1 has an edge E11 facing away the boundary 111 and an edge E12 facing the boundary 111, the active region AA2 has an edge E21 facing away the boundary 111 and an edge E22 facing the boundary 111, and the active region AA3 has an edge E31 facing away the boundary 111 and an edge E32 facing the boundary 111. In some embodiments, as shown in FIG. 1, the edge E11 of the active region AA1 is aligned with the edge E21 of the active region AA2, and the opposite edge E12 of the active region AA1 is aligned with the edge E32 of the active region AA3. In the disclosure, such configuration of the active regions AA1 to AA3 in the same row is beneficial to provide a compact layout including devices having different channel widths in adjacent circuits, so as to achieve both high speed and low power consumption requirement.

In some embodiments, the active region AA4 has an edge E41 facing away the boundary 111 and an edge E42 facing the boundary 111, the active region AA5 has an edge E51 facing away the boundary 111 and an edge E52 facing the boundary 111, and the active region AA6 has an edge E61 facing away the boundary 111 and an edge E62 facing the boundary 111. In some embodiments, as shown in FIG. 1, the edge E41 of the active region AA4 is aligned with the edge E51 of the active region AA5, and the opposite edge E42 of the active region AA4 is aligned with the edge E62 of the active region AA6. In the disclosure, such configuration of the active regions AA4 to AA6 in the same row is beneficial to provide a compact layout including devices having different channel widths in adjacent circuits, so as to achieve both high speed and low power consumption requirement.

As shown in FIG. 1, the active regions AA1-AA6 have widths W1-W6 respectively. In some embodiments, the width W1 of the active region AA1 is greater than the width W2 of the active region AA2 or the width W3 of the active region AA3. The width W2 of the active region AA2 may be equal to, less than or greater than the width W3 of the active region AA3. In other words, the active regions in the first region R1 may have at least two or at least three different widths (e.g., channel widths).

In some embodiments, the width W4 of the active region AA4 is greater than the width W5 of the active region AA5 or the width W6 of the active region AA6. The width W5 of the active region AA5 may be equal to, less than or greater than the width W6 of the active region AA6. In other words, the active regions in the first region R2 may have at least two or at least three different widths (e.g., channel widths).

In some embodiments, the ratio of the width W1 to the width W2 may range from about 1.1 to 3, and the ratio of the width W1 to the width W3 may range from about 1.1 to 3. In some embodiments, the ratio of the width W4 to the width W5 may range from about 1.1 to 3, and the ratio of the width W4 to the width W6 may range from about 1.1 to 3. In some embodiments, the ratio of the width W1 to the width W4 may range from about 1.1 to 3. However, the present disclosure is not limited thereto. In other embodiments, the ratio of the width W1 to the width W4 may range from about 0.5 to 1.

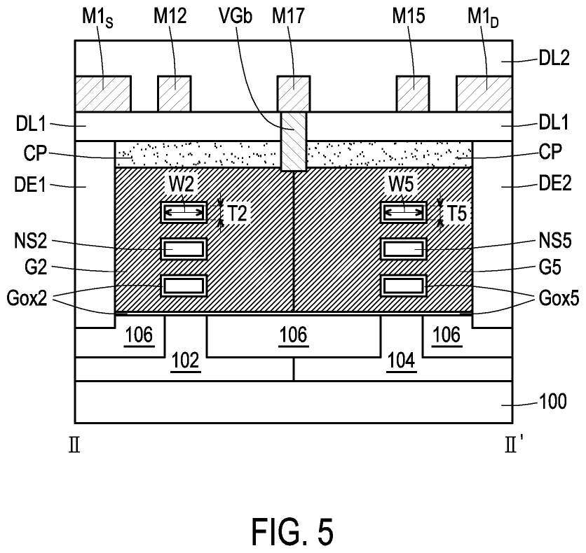

In some embodiments, the active regions AA1, AA2, AA3, AA4, AA5 and AA6 are defined by isolation structures 106 (see FIGS. 4-5), so they are referred to as oxide-definition (OD) regions. The isolation structures 106 include one or more insulating materials, such as silicon oxide. The isolation structures 106 are referred to as “isolation strips”, “shallow trench isolation (STI) regions” or “deep trench isolation (DTI) regions” in some examples.

The substrate 100 may include various doped regions (e.g., P-type well region and/or N-type well region) depending on design requirements. For example, as shown in FIGS. 4 and 5, the substrate 100 has a well region 102 (e.g., P-type well region) in the first region R1 and has a well region 104 (e.g., N-type well region) in the second region R2.

As shown in FIG. 1, the semiconductor device 10 further includes gate electrodes G1, G2 and G3 in the first region R1 and gate electrodes G4, G5 and G6 in the second region R2. The gate electrodes G1, G2, G3, G4, G5 and G6 extend in the second direction D2, and across the active regions AA1, AA2, AA3, AA4, AA5 and AA6, respectively.

In some embodiments, the gate electrodes G1 and G4 are aligned with and connected to each other, the gate electrodes G2 and G5 are aligned with and connected to each other, and the gate electrodes G3 and G6 are aligned with and connected to each other. However, the disclosure is not limited thereto. In other embodiments, an insulating region may be defined between the gate electrodes G1 and G4, between the gate electrodes G2 and G5, and between the gate electrodes G3 and G6.

As shown in FIG. 1 and FIGS. 4-5, nanosheets NS1 are vertically stacked in the active region AA1 and surrounded by the gate electrode G1, nanosheets NS2 are vertically stacked in the active region AA2 and surrounded by the gate electrode G2, and nanosheets NS3 are vertically stacked in the active region AA3 and surrounded by the gate electrode G3. In some embodiments, the width W1 of the active region AA1 is the channel width W1 of the nanosheets NS1, the width W2 of the active region AA2 is the channel width W2 of the nanosheets NS2, and the width W3 of the active region AA3 is the channel width W3 of the nanosheets NS3. The cannel widths are referred to as “sheet widths” in some examples. In some embodiments, for an N-type device, the nanosheets NS1 to NS3 include silicon or the like, and the gate electrodes G1 to G3 include an N-type work function metal layer and a metal filling layer. The N-type work function metal layer includes one or more of TaN, TaAlC, TiN, TiC, Co, TiAl, HfTi, TiSi and TaSi. The metal filling layer includes Al, W, Cu or the like.

In some embodiments, a gate dielectric layer Gox1 is formed between each nanosheet NS1 and the gate electrode G1, a gate dielectric layer Gox2 is formed between each nanosheet NS2 and the gate electrode G2, and a gate dielectric layer Gox3 is formed between each nanosheet NS3 and the gate electrode G3. The gate dielectric layers Gox1 to Gox3 include a high-k material. Examples of the high-k material include metal oxide, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, the like, or combinations thereof.

As shown in FIG. 1 and FIGS. 4-6, nanosheets NS4 are vertically stacked in the active region AA4 and surrounded by the gate electrode G4, nanosheets NS5 are vertically stacked in the active region AA5 and surrounded by the gate electrode G5, and nanosheets NS6 are vertically stacked in the active region AA6 and surrounded by the gate electrode G6. In some embodiments, the width W4 of the active region AA4 is the channel width W4 of the nanosheets NS4, the width W5 of the active region AA5 is the channel width W5 of the nanosheets NS5, and the width W6 of the active region AA6 is the channel width W6 of the nanosheets NS6. The cannel widths are referred to as “sheet widths” in some examples. In some embodiments, for a P-type device, the nanosheets NS4 to NS6 include silicon, silicon germanium, the like or a combination thereof, and the gate electrodes G4 to G6 include a P-type work function metal layer and a metal filling layer. The P-type work function metal layer includes one or more of TiAlC, Al, TiAl, TaN, TaAlC, TIN, TiC and Co. The metal filling layer includes Al, W, Cu or the like.

In some embodiments, a gate dielectric layer Gox4 is formed between each nanosheet NS4 and the gate electrode G4, a gate dielectric layer Gox5 is formed between each nanosheet NS5 and the gate electrode G5, and a gate dielectric layer Gox6 is formed between each nanosheet NS6 and the gate electrode G6. The gate dielectric layers Gox4 to Gox6 include a high-k material. Examples of the high-k material include metal oxide, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, the like, or combinations thereof.

In some embodiments, the thickness T1 of the nanosheets NS1 may be equal to the thickness T2 of the nanosheets NS2 or the thickness T3 of the nanosheets NS3, and the thickness T4 of the nanosheets NS4 may be equal to the thickness T5 of the nanosheets NS5 or the thickness T6 of the nanosheets NS6. In some embodiments, the thickness T1 of the nanosheets NS1 may be equal to the thickness T4 of the nanosheets NS4, the thickness T2 of the nanosheets NS2 may be equal to the thickness T5 of the nanosheets NS5, and the thickness T3 of the nanosheets NS3 may be equal to the thickness T6 of the nanosheets NS6. In other embodiments, the thickness of at least one of the nanosheets is different from the thickness of another nanosheet.

As shown in FIG. 1, the semiconductor device 10 further includes dielectric walls DW1 to DW4 extend in the second direction D2 and across the first region R1 and the second region R2. The dielectric walls DW1 to DW4 are defined to isolate the active regions AA1, AA2, AA3, AA4, AA5 and AA6 from each other. Specifically, the dielectric walls DW1 and DW2 are disposed at two sides of the active regions AA2 and AA5, the dielectric walls DW2 and DW3 are disposed at two sides of the active regions AA1 and AA4, and the dielectric walls DW3 and DW4 are disposed at two sides of the active regions AA3 and AA6. Each of the dielectric walls DW1 to DW4 may have a single-layer or multi-layer structure. In some embodiments, the dielectric walls DW1 to DW4 include silicon oxide, silicon nitride, SiON, SiC, SiCN, SiCON, or a combination thereof. The dielectric walls DW1 to DW4 are referred to “dummy walls” or “dielectric gates” in some examples.

In some embodiments, the semiconductor device 10 further includes spacers 110 on sidewalls of each of the gate electrodes G1 to G6 and the dielectric walls DW1 to DW4. Each of the spacers 110 may have a single-layer or multi-layer structure. In some embodiments, the spacers 232 include a dielectric material, such as silicon oxide, silicon nitride, SION, SIC, SiCN, SiCON, or a combination thereof. Other materials such as a low-k material may be applicable. The spacers 110 are referred to as “inner spacers” or “sidewall spacers” in some examples.

As shown in FIGS. 4-9, strained layers 112 are formed at two sides of each of the gate electrodes G1, G2 and G3 in the first region R1, and strained layers 114 are formed at two sides of each of the gate electrodes G4, G5 and G6 in the second region R2. The strained layers may be referred to as “epitaxial layers”, “source/drain regions” or “highly doped low resistance materials” in some examples. “Source/drain region(s) may refer to a source or a drain, individually or collectively dependent upon the context.

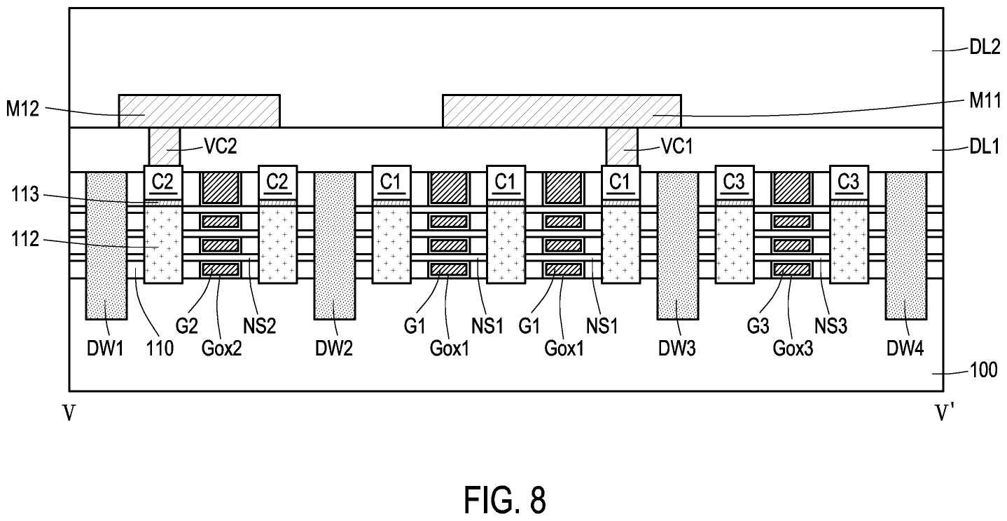

The strained layers 112 are abutted and electrically connected to the nanosheets NS1. NS2 and NS3, while the strained layers 112 are electrically isolated from the gate electrodes G1, G2 and G3 by the inner spacers 110. In some embodiments, for an N-type device, the strained layers 112 may include silicon, SiC, SiCP, SiP, or the like. In some embodiments, as shown in FIG. 8, silicide layers 113 are optionally formed over the strained layers 112 respectively. The silicide layers 113 may include tungsten silicide, cobalt silicide, titanium silicide, nickel silicide, the like or a combination thereof.

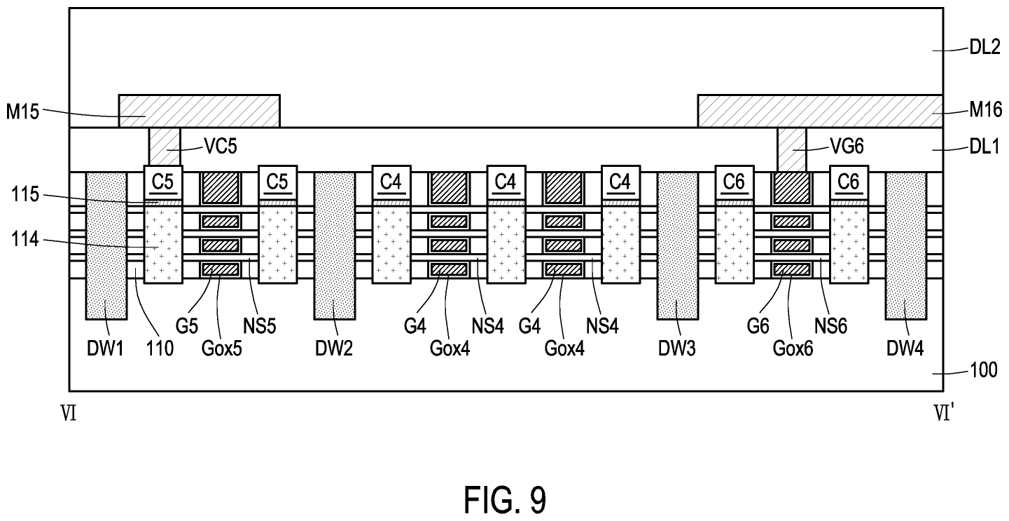

The strained layers 114 are abutted and electrically connected to the nanosheets NS4, NS5 and NS6, while the strained layers 114 are electrically isolated from the gate electrodes G4, G5 and G6 by the inner spacers 110. In some embodiments, for a P-type device, the strained layers 114 may include SiGe, SiGeB, Ge, GeSn, or the like. In some embodiments, as shown in FIG. 9, silicide layers 115 are optionally formed over the strained layers 114 respectively. The silicide layers 115 may include tungsten silicide, cobalt silicide, titanium silicide, nickel silicide, the like or a combination thereof.

In some embodiments, as shown in FIG. 1 and FIGS. 4-9, the semiconductor device 10 further includes dielectric ends DE1 and DE2 at opposite ends of each of the gate electrodes G1 to G6 and the dielectric walls DW1 to DW4, as shown in FIG. 1. Each of the dielectric ends DE1 and DE2 may have a single-layer or multi-layer structure. In some embodiments, the dielectric ends DE1 and DE2 include a dielectric material, such as silicon oxide, silicon nitride, SiON, SiC, SiCN, SiCON, or a combination thereof. Other materials such as a low-k material may be applicable. The dielectric ends DE1 and DE2 are referred to as “end spacers” in some examples.

In some embodiments, as shown in FIGS. 4-6, a cap layer CP is formed over the gate electrodes G1-G6 and between the dielectric ends DE1 and DE2. The cap layer CP includes a dielectric cap. The cap layer CP includes silicon oxide, silicon nitride, SION, SiC, SiCN, SiCON, metal oxide (e.g., Al₂O₃) or a combination thereof.

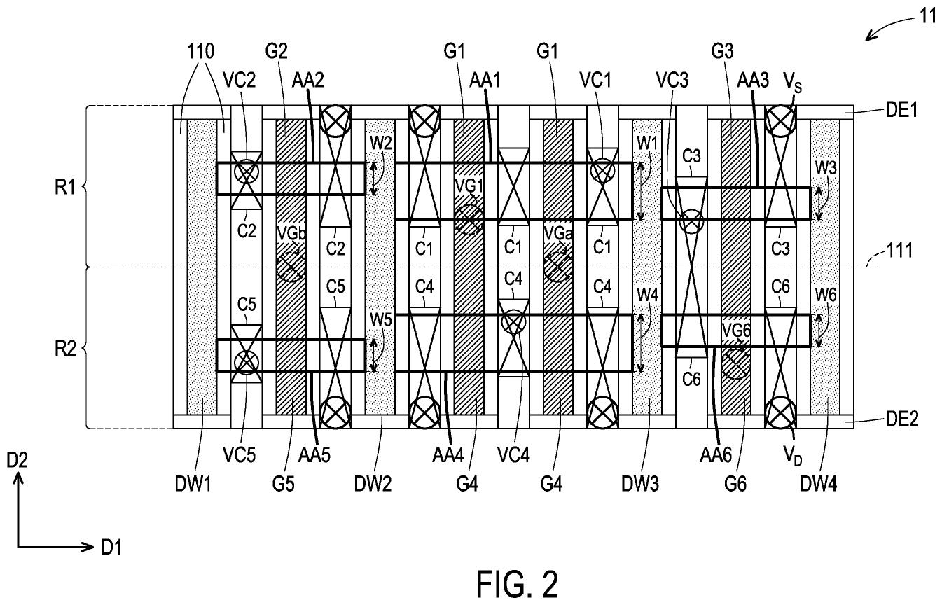

Referring to FIG. 2 and FIGS. 4-9, a semiconductor device 11 further includes metal contacts and zeroth vias in addition to the elements described in FIG. 1.

The metal contacts are landed on and electrically connected to the corresponding strained layers. In some embodiments, the metal contacts C1, C2 and C3 overlap with the active regions AA1, AA2 and AA3 respectively, and the metal contacts C4, C5 and C6 overlap with the active regions AA4, AA5 and AA6 respectively. In some embodiments, the metal contacts C1, C2 and C3 are formed at two sides of each of the gate electrodes G1, G2 and G3 and electrically connected to the corresponding strained layers 112 in the first region R1, and metal contacts C4, C5 and C6 are formed at two sides of each of the gate electrodes G4, G5 and G6 and electrically connected to the corresponding strained layers 114 in the second region R2. The metal contacts may have a rectangular shape from a top view. The metal contacts may extend along the second direction D2. The metal contacts may be referred to as “long contacts” in some examples.

In some embodiments, the metal contacts are embedded in a dielectric layer DL1. The dielectric layer DL1 is referred to as an “interlayer dielectric (ILD) layer” in some embodiments. The metal contacts include Cu, Al, Ti, Ta, W, Ru, Co, Ni, the like, or a combination thereof. In some embodiments, a metal liner layer may be disposed between each metal contact and the dielectric layer DL1. In some embodiments, the metal liner layer includes a seed layer and/or a barrier layer. The seed layer may include Ti/Cu. The barrier layer may include Ta, TaN, Ti, TiN, CoW or a combination thereof. The dielectric layer DL1 may include silicon oxide, silicon oxynitride, silicon nitride, a low low-k material having a dielectric constant less than 3.5, the like, or a combination thereof.

In some embodiments, some metal contacts (e.g., C1, C2. C4 and C5) are separated from each other. In some embodiments, some metal contacts (e.g., C3 and C6) are connected to each other. In some embodiments, some metal contacts (e.g., one C1, one C2 and one C3) are configured to electrically connected to a source voltage V_{SS}. In some embodiments, some metal contacts (e.g., one C4, one C5 and one C6) are configured to electrically connected to a drain voltage V_{DD}.

The zeroth vias include gate vias VG (or called “gate contacts”) landed on and electrically connected to the corresponding gate electrodes, and contact vias VC landed on and electrically connected to the corresponding metal contacts.

In some embodiments, some gate vias (e.g., VG1 and VG6) are landed on the corresponding gate electrodes (e.g., G1 and G6). In some embodiments, some vias (e.g., VGa and VGb) are landed on two gate electrodes. For example, the via VGa are disposed at the boundary 111 between the first and second regions R1 and R2 and in direct contact with the gate electrodes G1 and G4. For example, the via VGb are disposed at the boundary 111 between the first and second regions R1 and R2 and in direct contact with the gate electrodes G2 and G5. In some embodiments, some vias (e.g., VC1, VC2, VC3, VC4, VC5) are disposed on the corresponding metal contacts (e.g., C1, C2, C3, C4, C5) that are electrically connected to the subsequently formed metal lines. In some embodiments, some vias (e.g., V_{S}) are disposed on the corresponding metal contacts that are electrically connected to a source voltage V_{SS}. In some embodiments, some vias (e.g., V_{D}) are disposed on the corresponding metal contacts that are electrically connected to a source voltage V_{DD}.

In some embodiments, the zeroth vias are embedded in the dielectric layer DL1. The dielectric layer DL1 is referred to as an “interlayer dielectric (ILD) layer” in some embodiments. The zeroth vias include Cu, Al, Ti, Ta, W, Ru, Co, Ni, the like, or a combination thereof. In some embodiments, a metal liner layer may be disposed between each zeroth via and the dielectric layer DL1. In some embodiments, the metal liner layer includes a seed layer and/or a barrier layer. The seed layer may include Ti/Cu. The barrier layer may include Ta, TaN, Ti, TiN, CoW or a combination thereof. The dielectric layer DL1 may include silicon oxide, silicon oxynitride, silicon nitride, a low low-k material having a dielectric constant less than 3.5, the like, or a combination thereof.

Referring to FIG. 3 and FIGS. 4-9, a semiconductor device 12 further includes metal lines (or called “routing tracks”) in addition to the elements described in FIG. 1 and FIG. 2.

The metal lines are landed on and electrically connected to the corresponding zeroth vias. The metal lines are defined simultaneously and substantially at the same level. The metal lines are collectively referred to a first metal layer in some examples. In some embodiments, the metal lines M11, M12 and M13 overlap with the active regions AA1, AA2 and AA3 respectively, and the metal lines M14, M15 and M16 overlap with the active regions AA4, AA5 and AA6 respectively. In some embodiments, the metal lines M11, M12 and M13 are formed across the gate electrodes G1, G2 and G3 and electrically connected to the corresponding vias in the first region R1, and metal lines M14, M15 and M16 are formed across the gate electrodes G4, G5 and G6 and electrically connected to the corresponding vias in the second region R2. The metal lines may extend along the first direction D1.

In some embodiments, some metal lines (e.g., M11, M12, M13, M14, M15) are disposed on and electrically connected to the corresponding vias (e.g., VC1, VC2, VC3, VC4, VC5). In some embodiments, at least one metal line (e.g., M1_{S}) is disposed on and electrically connected to the corresponding metal vias that are electrically connected to a source voltage V_{SS}. In some embodiments, at least one metal line (e.g., M1_{D}) is disposed on and electrically connected to the corresponding metal vias that are electrically connected to a source voltage V_{DD}. In some embodiments, some metal lines (e.g., M17) are disposed at the boundary 111 between the first and second regions R1 and R2 and electrically connected to the corresponding metal vias (e.g., V1a and V1b).

In some embodiments, the metal lines are embedded in a dielectric layer DL2. The dielectric layer DL2 is referred to as an “inter-metal dielectric (IMD) layer” in some embodiments. The metal lines include Cu, Al, Ti, Ta, W, Ru, Co, Ni, the like, or a combination thereof. In some embodiments, a metal liner layer may be disposed between each metal line and the dielectric layer DL2. In some embodiments, the metal liner layer includes a seed layer and/or a barrier layer. The seed layer may include Ti/Cu. The barrier layer may include Ta, TaN, Ti, TiN, CoW or a combination thereof. The dielectric layer DL2 may include silicon oxide, silicon oxynitride, silicon nitride, a low low-k material having a dielectric constant less than 3.5, the like, or a combination thereof.

Some devices with narrower channel/sheet widths have better gate control due to smaller channel regions and can serve for non-speed critical circuit to have both lower leakage and power consumption advantages. Some devices with wider channel/sheet widths have wider channel width for high speed application, but the leakage may worse than nanowire device. The present disclosure provides a mixed layout including both devices in adjacent circuits, so as to achieve both high speed and low power consumption requirement. The novel configurations of active regions are beneficial to provide a compact layout and therefore reduce the layout area.

In above embodiments, from a top view, the active regions AA1, AA2 and AA3 are arranged symmetrically to the active regions AA4, AA5 and AA6 with respect to the boundary 111 between the first region R1 and the second region R2, as shown in FIG. 1 to FIG. 3. Specifically, the distance from the active region AA1 to the boundary 111 may be substantially equal to the distance from the active region AA4 to the boundary 111, the distance from the active region AA2 to the boundary 111 may be substantially equal to the distance from the active region AA5 to the boundary 111, and the distance from the active region AA3 to the boundary 111 may be substantially equal to the distance from the active region AA6 to the boundary 111. From another point of view, the active regions AA2 and AA5 are shifted towards different directions, and the active regions AA3 and AA5 are shifted towards different directions.

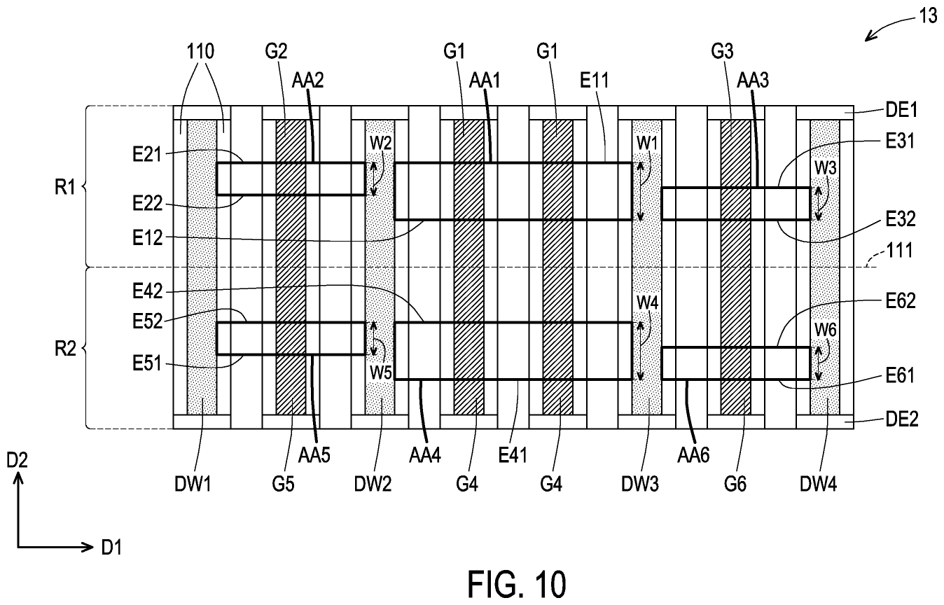

However, the disclosure is not limited thereto. In other embodiments, from a top view, the active regions AA1, AA2 and AA3 are arranged asymmetrically to the active regions AA4, AA5 and AA6 with respect to the boundary 111 between the first region R1 and the second region R2, as shown in FIG. 10 to FIG. 12.

FIG. 10 to FIG. 12 are top views of a layout of a semiconductor device construed at various fabrication stages in accordance with some embodiments. In some embodiments, the layout is stored in a computer or a non-transitory computer-readable medium. The elements shown in FIGS. 4-9 are also included in FIGS. 10-12, but the element configurations may be different. Similar terms indicate similar elements, so element materials are not iterated herein. The element configurations in cross-sectional views can be easily drawn for people having ordinary skilled in the art according to the top views of FIG. 10 to FIG. 12.

Referring to FIG. 10, a semiconductor device 13 includes a substrate. The semiconductor device 13 includes a first region R1 and a second region R2 adjacent to each other and having a boundary 111 therebetween. The first region R1 and the second region R2 are both device regions. The devices may include active components and/or passive components. In some embodiments, each device includes a gate-all-around (GAA) device, but the disclosure is not limited thereto. In other embodiments, each device may include a fin-type field effect transistor (FinFET) device, a planar device such as a metal oxide semiconductor field effect transistor (MOSFET) device, or the like. In some embodiments, the first region R1 is an N-type device region, and the second region R2 is a P-type device region. However, the disclosure is not limited thereto. In other embodiments, the first region R1 is a P-type device region, and the second region R2 is an N-type device region. In some embodiments, the devices in the first region R1 and the second region R2 constitute a complementary metal oxide semiconductor (CMOS) transistor, and the boundary 111 between the first region R1 and the second region R2 may be referred to as an N—P boundary.

As shown in FIG. 10, the semiconductor device 13 further includes active regions AA1, AA2 and AA3 with different widths in the first region R1 and active regions AA4, AA5 and AA6 with different widths in the second region R2. The active regions AA1, AA2, AA3, AA4, AA5 and AA6 extend in a first direction D1. The first direction D1 may be a X-direction. In some embodiments, the active region AA1 is disposed between the active regions AA2 and AA3, and the active region AA4 is disposed between the active regions AA5 and AA6. However, the present disclosure is not limited thereto. The locations of active regions can be adjusted as needed. For example, the active region AA2 may be disposed between the active regions AA1 and AA3, and the active region AA5 may be disposed between the active regions AA4 and AA6.

From another point of view, the active regions AA1, AA2 and AA3 in the first region R1 may be regarded as active regions arranged in a first row, while the active regions AA4, AA5 and AA6 in the second region R2 may be regarded as active regions arranged in a second row. The active regions AA1 and AA4 in different regions R1 and R2 may be regarded as active regions arranged in a first column, the active regions AA2 and AA5 in different regions R1 and R2 may be regarded as active regions arranged in a second column, and the active regions AA3 and AA6 in different regions R1 and R2 may be regarded as active regions arranged in a third column.

In some embodiments, the widths of the active regions AA1, AA2, AA3, AA4, AA5 and AA6 are defined as widths measured along a second direction D2 different from the first direction D1. The second direction D2 may be a Y-direction.

In some embodiments, the active region AA1 has an edge E11 facing away the boundary 111 and an edge E12 facing the boundary 111, the active region AA2 has an edge E21 facing away the boundary 111 and an edge E22 facing the boundary 111, and the active region AA3 has an edge E31 facing away the boundary 111 and an edge E32 facing the boundary 111. In some embodiments, as shown in FIG. 10, the edge E11 of the active region AA1 is aligned with the edge E21 of the active region AA2, and the opposite edge E12 of the active region AA1 is aligned with the edge E32 of the active region AA3. In the disclosure, such configuration of the active regions AA1 to AA3 in the same row is beneficial to provide a compact layout including devices having different channel widths in adjacent circuits, so as to achieve both high speed and low power consumption requirement.

In some embodiments, the active region AA4 has an edge E41 facing away the boundary 111 and an edge E42 facing the boundary 111, the active region AA5 has an edge E51 facing away the boundary 111 and an edge E52 facing the boundary 111, and the active region AA6 has an edge E61 facing away the boundary 111 and an edge E62 facing the boundary 111. In some embodiments, as shown in FIG. 10, the edge E41 of the active region AA4 is aligned with the edge E61 of the active region AA6, and the opposite edge E42 of the active region AA4 is aligned with the edge E52 of the active region AA5. In the disclosure, such configuration of the active regions AA4 to AA6 in the same row is beneficial to provide a compact layout including devices having different channel widths in adjacent circuits, so as to achieve both high speed and low power consumption requirement.

As shown in FIG. 10, from a top view, the active regions AA1, AA2 and AA3 are arranged asymmetrically to the active regions AA4, AA5 and AA6 with respect to the boundary 111 between the first region R1 and the second region R2.

From another point of view, the active regions AA2 and AA5 are shifted towards the same direction (e.g., upward direction), and the active regions AA3 and AA5 are shifted towards the same direction (e.g., downward direction). Specifically, the distance from the active region AA2 to the boundary 111 may be different from the distance from the active region AA5 to the boundary 111, and the distance from the active region AA3 to the boundary 111 may be different from the distance from the active region AA6 to the boundary 111.

As shown in FIG. 10, the active regions AA1-AA6 have widths W1-W6 respectively. In some embodiments, the width W1 of the active region AA1 is greater than the width W2 of the active region AA2 or the width W3 of the active region AA3. The width W2 of the active region AA2 may be equal to, less than or greater than the width W3 of the active region AA3. In other words, the active regions in the first region R1 may have at least two or at least three different widths (e.g., channel widths).

In some embodiments, the width W4 of the active region AA4 is greater than the width W5 of the active region AA5 or the width W6 of the active region AA6. The width W5 of the active region AA5 may be equal to, less than or greater than the width W6 of the active region AA6. In other words, the active regions in the first region R2 may have at least two or at least three different widths (e.g., channel widths).

In some embodiments, the ratio of the width W1 to the width W2 may range from about 1.1 to 3, and the ratio of the width W1 to the width W3 may range from about 1.1 to 3. In some embodiments, the ratio of the width W4 to the width W5 may range from about 1.1 to 3, and the ratio of the width W4 to the width W6 may range from about 1.1 to 3. In some embodiments, the ratio of the width W1 to the width W4 may range from about 1.1 to 3. However, the present disclosure is not limited thereto. In other embodiments, the ratio of the width W1 to the width W4 may range from about 0.5 to 1.

In some embodiments, the active regions AA1, AA2, AA3, AA4, AA5 and AA6 are defined by isolation structures, so they are referred to as oxide-definition (OD) regions. The substrate 100 may include various doped regions (e.g., P-type well region and/or N-type well region) depending on design requirements. For example, the substrate has a well region (e.g., P-type well region) in the first region R1 and has a well region (e.g., N-type well region) in the second region R2.

As shown in FIG. 10, the semiconductor device 13 further includes gate electrodes G1, G2 and G3 in the first region R1 and gate electrodes G4, G5 and G6 in the second region R2. The gate electrodes G1, G2, G3, G4, G5 and G6 extend in the second direction D2, and across the active regions AA1, AA2, AA3, AA4, AA5 and AA6, respectively.

In some embodiments, the gate electrodes G1 and G4 are aligned with and connected to each other, the gate electrodes G2 and G5 are aligned with and connected to each other, and the gate electrodes G3 and G6 are aligned with and connected to each other. However, the disclosure is not limited thereto. In other embodiments, an insulating region may be defined between the gate electrodes G1 and G4, between the gate electrodes G2 and G5, and between the gate electrodes G3 and G6.

In some embodiments, first nanosheets are vertically stacked in the active region AA1 and surrounded by the gate electrode G1, second nanosheets are vertically stacked in the active region AA2 and surrounded by the gate electrode G2, and third nanosheets are vertically stacked in the active region AA3 and surrounded by the gate electrode G3. In some embodiments, the width W1 of the active region AA1 is the channel width W1 of the first nanosheets, the width W2 of the active region AA2 is the channel width W2 of the second nanosheets, and the width W3 of the active region AA3 is the channel width W3 of the third nanosheets. The cannel widths are referred to as “sheet widths” in some examples. In some embodiments, a gate dielectric layer is formed between each nanosheet and the corresponding gate electrode.

In some embodiments, fourth nanosheets are vertically stacked in the active region AA4 and surrounded by the gate electrode G4, fifth nanosheets are vertically stacked in the active region AA5 and surrounded by the gate electrode G5, and sixth nanosheets are vertically stacked in the active region AA5 and surrounded by the gate electrode G6. In some embodiments, the width W4 of the active region AA4 is the channel width W4 of the fourth nanosheets, the width W5 of the active region AA5 is the channel width W5 of the fifth nanosheets, and the width W6 of the active region AA6 is the channel width W6 of the sixth nanosheets. The cannel widths are referred to as “sheet widths” in some examples. In some embodiments, a gate dielectric layer is formed between each nanosheet and the corresponding gate electrode.

In some embodiments, the thickness of each nanosheet is the same. In other embodiments, the thickness of at least one of the nanosheets is different from the thickness of another nanosheet.

As shown in FIG. 10, the semiconductor device 13 further includes dielectric walls DW1 to DW4 extend in the second direction D2 and across the first region R1 and the second region R2. The dielectric walls DW1 to DW4 are defined to isolate the active regions AA1, AA2, AA3, AA4, AA5 and AA6 from each other. Specifically, the dielectric walls DW1 and DW2 are disposed at two sides of the active regions AA2 and AA5, the dielectric walls DW2 and DW3 are disposed at two sides of the active regions AA1 and AA4, and the dielectric walls DW3 and DW4 are disposed at two sides of the active regions AA3 and AA6.

In some embodiments, the semiconductor device 13 further includes spacers 110 on sidewalls of each of the gate electrodes G1 to G6 and the dielectric walls DW1 to DW4, as shown in FIG. 10.

In some embodiments, first strained layers are formed at two sides of each of the gate electrodes G1, G2 and G3 in the first region R1, and second strained layers are formed at two sides of each of the gate electrodes G4. G5 and G6 in the second region R2. The first strained layers are abutted and electrically connected to the first to third nanosheets, while the first strained layers are electrically isolated from the gate electrodes G1, G2 and G3 by the inner spacers 110. In some embodiments, silicide layers are optionally formed over the first strained layers respectively. The second strained layers are abutted and electrically connected to the fourth to sixth nanosheets, while the second strained layers are electrically isolated from the gate electrodes G4, G5 and G6 by the inner spacers 110. In some embodiments, silicide layers are optionally formed over the second strained layers respectively.

In some embodiments, as shown in FIG. 10, the semiconductor device 13 further includes dielectric ends DE1 and DE2 at opposite ends of each of the gate electrodes G1 to G6 and the dielectric walls DW1 to DW4. In some embodiments, a cap layer is formed over the gate electrodes G1-G6 and between the dielectric ends DE1 and DE2.

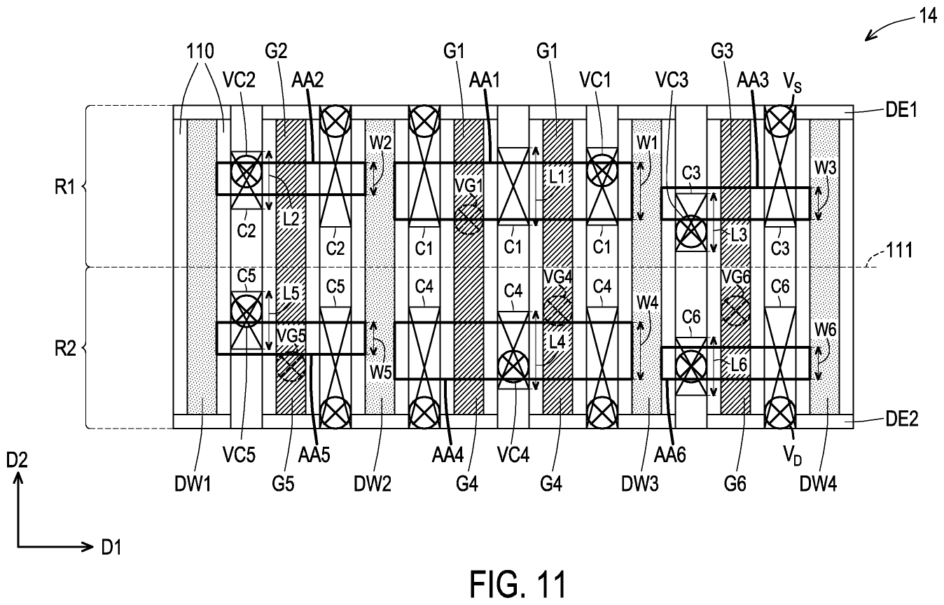

Referring to FIG. 11, a semiconductor device 14 further includes metal contacts and zeroth vias in addition to the elements described in FIG. 10.

The metal contacts are landed on and electrically connected to the corresponding strained layers. In some embodiments, the metal contacts C1, C2 and C3 overlap with the active regions AA1, AA2 and AA3 respectively, and the metal contacts C4, C5 and C6 overlap with the active regions AA4, AA5 and AA6 respectively. In some embodiments, the metal contacts C1, C2 and C3 are formed at two sides of each of the gate electrodes G1. G2 and G3 and electrically connected to the corresponding strained layers in the first region R1, and metal contacts C4, C5 and C6 are formed at two sides of each of the gate electrodes G4, G5 and G6 and electrically connected to the corresponding strained layers in the second region R2. The metal contacts may have a rectangular shape from a top view. The metal contacts may extend along the second direction D2. The metal contacts may be referred to as “long contacts” in some examples. In some embodiments, the metal contacts are embedded in an interlayer dielectric (ILD) layer.

The metal contacts C1, C2, C3, C4, C5 and C6 are separated from each other. In some embodiments, some metal contacts (e.g., one C1, one C2 and one C3) are configured to electrically connected to a source voltage V_{SS}. In some embodiments, some metal contacts (e.g., one C4, one C5 and one C6) are configured to electrically connected to a drain voltage V_{DD}.

The zeroth vias include gate vias VG (or called “gate contacts”) landed on and electrically connected to the corresponding gate electrodes, and contact vias VC landed on and electrically connected to the corresponding metal contacts.

In some embodiments, some gate vias (e.g., VG1, VG4, VG5 and VG6) are landed on the corresponding gate electrodes (e.g., G1, G4, G5 and G6). In some embodiments, some vias are optionally landed on two gate electrodes. In some embodiments, some vias (e.g., VC1, VC2, VC3, VC4, VC5, VC6) are disposed on the corresponding metal contacts (e.g., C1, C2, C3, C4, C5, C6) that are electrically connected to the subsequently formed metal lines. In some embodiments, some vias (e.g., V_{S}) are disposed on the corresponding metal contacts that are electrically connected to a source voltage V_{SS}. In some embodiments, some vias (e.g., V_{D}) are disposed on the corresponding metal contacts that are electrically connected to a source voltage V_{DD}. In some embodiments, the zeroth vias are embedded in the interlayer dielectric (ILD) layer.

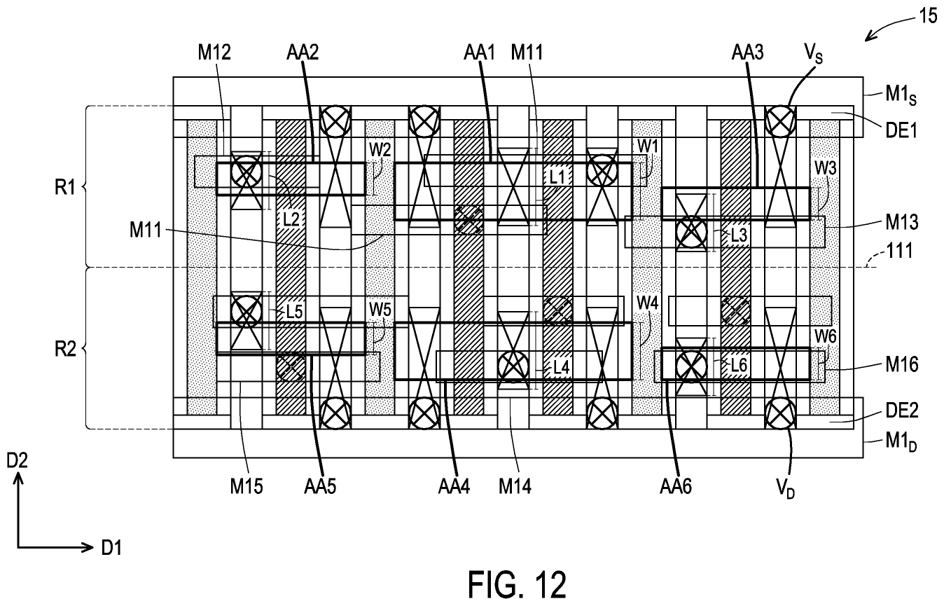

Referring to FIG. 12, a semiconductor device 15 further includes metal lines (or called “routing tracks”) in addition to the elements described in FIG. 10 and FIG. 11.

The metal lines are landed on and electrically connected to the corresponding zeroth vias. The metal lines are defined simultaneously and substantially at the same level. The metal lines are collectively referred to a first metal layer in some examples. In some embodiments, the metal lines M11, M12 and M13 overlap with the active regions AA1, AA2 and AA3 respectively, and the metal lines M14, M15 and M16 overlap with the active regions AA4, AA5 and AA6 respectively. In some embodiments, the metal lines M11, M12 and M13 are formed across the gate electrodes G1, G2 and G3 and electrically connected to the corresponding vias in the first region R1, and metal lines M14, M15 and M16 are formed across the gate electrodes G4, G5 and G6 and electrically connected to the corresponding vias in the second region R2. The metal lines may extend along the first direction D1.

In some embodiments, some metal lines (e.g., M11, M12, M13, M14, M15, M16) are disposed on and electrically connected to the corresponding vias (e.g., VC1, VC2, VC3, VC4, VC5, VC6). In some embodiments, at least one metal line (e.g., M1_{S}) is disposed on and electrically connected to the corresponding metal vias that are electrically connected to a source voltage V_{SS}. In some embodiments, at least one metal line (e.g., M1_{D}) is disposed on and electrically connected to the corresponding metal vias that are electrically connected to a source voltage V_{DD}. In some embodiments, some metal lines are optionally disposed at the boundary 111 and electrically connected to the corresponding metal vias at the boundary 111 between the first and second regions R1 and R2. In some embodiments, the metal lines are embedded in an inter-metal dielectric (IMD) layer.

As shown in FIGS. 11-12, the active regions AA1-AA6 have widths W1-W6 measured along the second direction D2, respectively. The metal contact C1-C6 (that are not electrically connected to a source voltage V_{SS} or a drain voltage V_{DD}) have lengths L1-L6 measured along the second direction D2, respectively.

In some embodiments, the width W1 is greater than the width W2 or the width W3, the length L1 is greater than the length L3, and the length L3 is greater than the length L2. In some embodiments, the width W4 is greater than the width W5 or the width W6, the length L4 is greater than the length L5, and the length L5 is greater than the length L6. From another point of view, in the first region R1, a contact length (e.g., L2) of one of the metal contacts (e.g., C2) farther away from the boundary 111 between the first and second regions R1 and R2 is shorter than a contact length (e.g., L3) of another of the metal contacts (e.g., C3) closer to the boundary 111 between the first and second regions R1 and R2. In the second region R2, a contact length (e.g., L6) of one of the metal contacts (e.g., C6) farther away from the boundary 111 between the first and second regions R1 and R2 is shorter than a contact length (e.g., L5) of another of the metal contacts (e.g., C5) closer to the boundary 111 between the first and second regions R1 and R2. With above element configurations, the contact layout area can be greatly reduced.

Some devices with narrower channel/sheet widths have better gate control due to smaller channel regions and can serve for non-speed critical circuit to have both lower leakage and power consumption advantages. Some devices with wider channel/sheet widths have wider channel width for high speed application, but the leakage may worse than nanowire device. The present disclosure provides a mixed layout including both devices in adjacent circuits, so as to achieve both high speed and low power consumption requirement. The novel configurations of active regions are beneficial to provide a compact layout and therefore reduce the layout area. Besides, the configuration of active regions of FIGS. 10-12 provides a novel contact deployment to fit both wider sheet devices and narrower sheet devices.

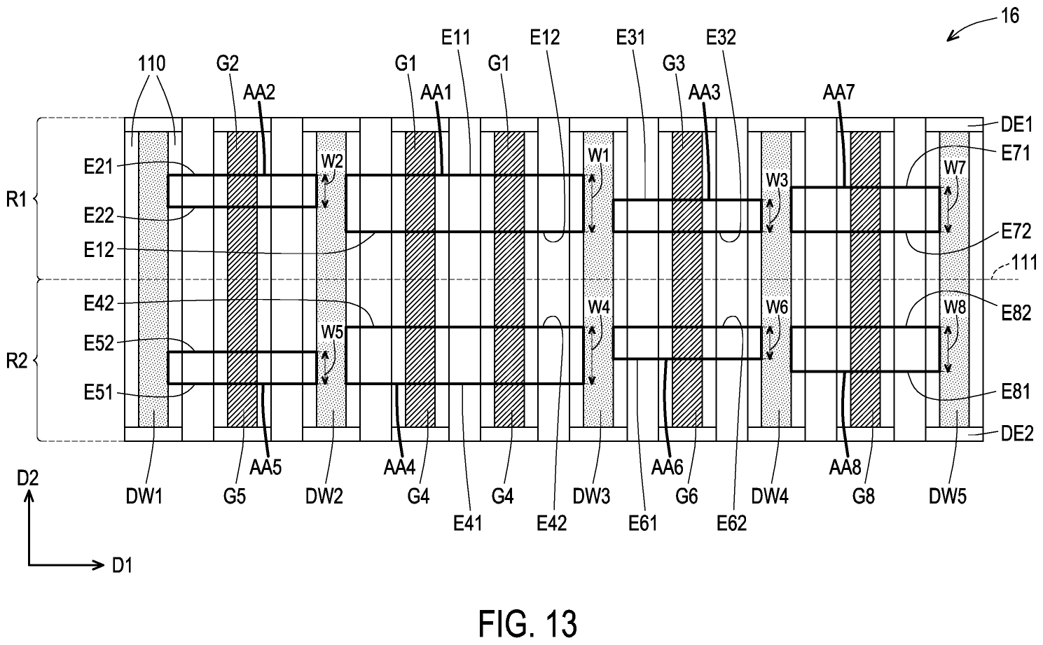

The above embodiments in which three different active regions are provided in each device region are provided for illustration purposes, and are not construed as limiting the present disclosure. In other embodiments, four or more active regions are provided in each device region, as shown in FIGS. 13-15.

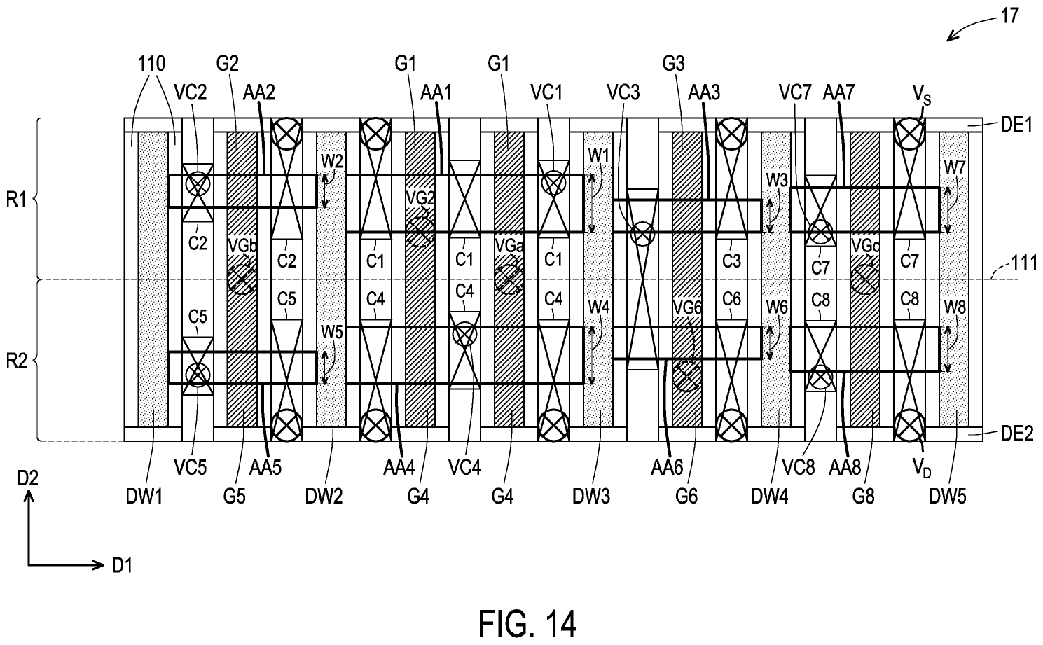

FIG. 13 to FIG. 14 are top views of a layout of a semiconductor device construed at various fabrication stages in accordance with some embodiments. In some embodiments, the layout is stored in a computer or a non-transitory computer-readable medium. The elements shown in FIGS. 4-9 are also included in FIGS. 13-14, but the element configurations may be different. Similar terms indicate similar elements, so element materials are not iterated herein. The element configurations in cross-sectional views can be easily drawn for people having ordinary skilled in the art according to the top views of FIGS. 13-14.

The semiconductor devices 16-17 of FIGS. 13-14 are similar to the semiconductor devices 10-11 of FIGS. 1-2. The difference between them is described in details below, and the similarity is not iterated herein.

As compared to the semiconductor device 10 of FIG. 1, the semiconductor device 16 of FIG. 13 further includes an active region AA7 in the first region R1 and an active region AA8 in the first region R2. Dielectric walls DW4 and DW5 are disposed at two sides of the active regions AA7 and AA8. In some embodiments, as shown in FIG. 13, in the first region R1, the width W1 is greater than the width W7, the width W7 is greater than the width W2 or W3. The width W2 may be equal to, less than or greater than the width W3. In the second region R2, the width W4 is greater than the width W8, the width W8 is greater than the width W5 or W6. The width W5 may be equal to, less than or greater than the width W6. In other words, the active regions in the first region R1 may have at least three or at least four different widths (e.g., channel widths or sheet widths), and the active regions in the second region R2 may have at least three or at least four different widths (e.g., channel widths or sheet widths).

In the first region R1, the edge E11 of the active region AA1 is aligned with the edge E21 of the active region AA2, and the opposite edge E12 of the active region AA1 is aligned with the edge E32 of the active region AA3 and the edge 72 of the active region AA7. In the disclosure, such configuration of the active regions AA1 to AA4 in the same row is beneficial to provide a compact layout including devices having different channel widths in adjacent circuits, so as to achieve both high speed and low power consumption requirement.

In the second region R2, the edge E41 of the active region AA4 is aligned with the edge E51 of the active region AA5, and the opposite edge E42 of the active region AA4 is aligned with the edge E62 of the active region AA6 and the edge E82 or the active region AA8. In the disclosure, such configuration of the active regions AA4 to AA6 in the same row is beneficial to provide a compact layout including devices having different channel widths in adjacent circuits, so as to achieve both high speed and low power consumption requirement.

As compared to the semiconductor device 10 of FIG. 1, the semiconductor device 16 of FIG. 13 further includes a gate electrode G7 across the active region AA7 and a gate electrode G8 across active region AA8. The gate electrodes G7 and G8 may be aligned with and connected to each other.

As compared to the semiconductor device 11 of FIG. 2, the semiconductor device 17 of FIG. 14 further includes metal contacts C7 and C8, and zeroth vias VC7, VC8 and VGc. The metal contacts C7 and C8 are landed on and electrically connected to the corresponding strained layers. The metal vias VC7 and VC8 are landed on and electrically connected to the corresponding metal contacts C7 and C8. The metal vias VGc are disposed at the boundary 111 and landed on two gate electrodes G7 and G8. Metal lines are subsequently formed to electrically connected to the metal contacts and/or zeroth vias. The metal lines can be configured in a manner similar to the layout rule of FIG. 3.

In above embodiments, from a top view, the active regions AA1, AA2, AA3 and AA7 are arranged symmetrically to the active regions AA4, AA5, AA6 and AA8 with respect to the boundary 111 between the first region R1 and the second region R2, as shown in FIG. 13 to FIG. 14. Specifically, the distance from the active region AA1 to the boundary 111 may be substantially equal to the distance from the active region AA4 to the boundary 111, the distance from the active region AA2 to the boundary 111 may be substantially equal to the distance from the active region AA5 to the boundary 111, the distance from the active region AA3 to the boundary 111 may be substantially equal to the distance from the active region AA6 to the boundary 111, and the distance from the active region AA7 to the boundary 111 may be substantially equal to the distance from the active region AA8 to the boundary 111. From another point of view, the active regions AA2 and AA5 are shifted towards different directions, the active regions AA3 and AA5 are shifted towards different directions, and the active regions AA7 and AA8 are shifted towards different directions.

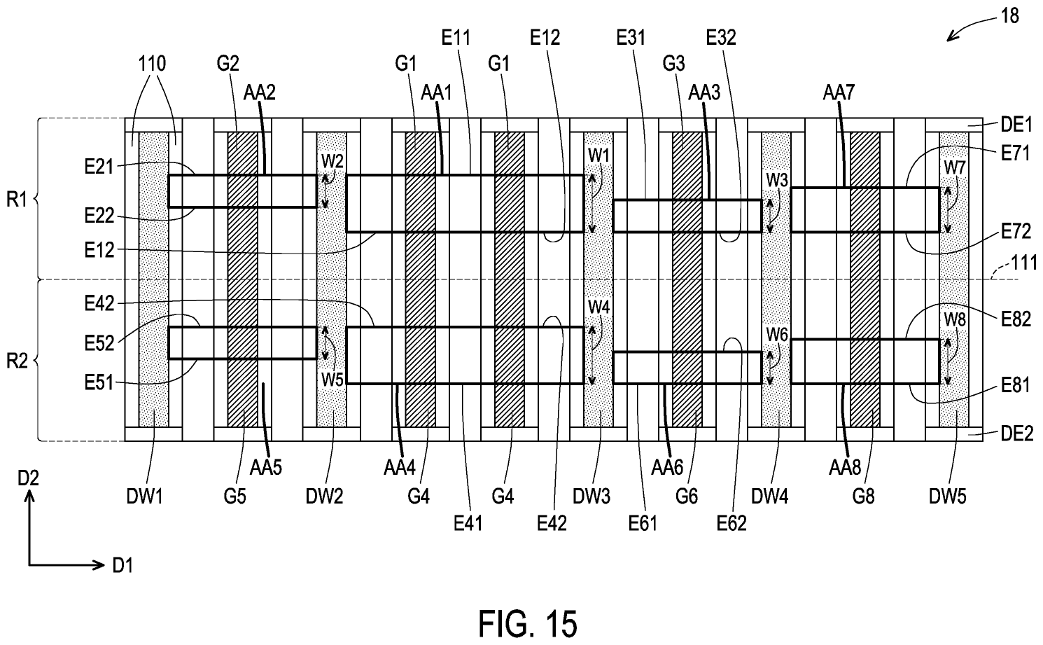

However, the disclosure is not limited thereto. In other embodiments, from a top view, the active regions AA1, AA2, AA3 and AA7 are arranged asymmetrically to the active regions AA4, AA5, AA6 and AA8 with respect to the boundary 111 between the first region R1 and the second region R2, as shown in FIG. 15.

As shown in FIG. 15, in the semiconductor device 18, the active regions AA2 and AA5 are shifted towards the same direction (e.g., upward direction), the active regions AA3 and AA5 are shifted towards the same direction (e.g., downward direction), and the active regions AA7 and AA8 are shifted towards the same direction (e.g., downward direction). Specifically, the distance from the active region AA2 to the boundary 111 may be different from the distance from the active region AA5 to the boundary 111, the distance from the active region AA3 to the boundary 111 may be different from the distance from the active region AA6 to the boundary 111, and the distance from the active region AA7 to the boundary 111 may be different from the distance from the active region AA8 to the boundary 111. Metal contacts, zeroth vias, and metal lines are subsequently formed to electrically connected to the corresponding strained layers and/or gate electrodes. The metal contacts, the zeroth vias, and the metal lines can be configured in a manner similar to the layout rule of FIG. 11 and FIG. 12.

In view of the above, the present disclosure provides a mixed layout including both devices in adjacent circuits, so as to achieve both high speed and low power consumption requirement. The novel configurations of active regions are beneficial to reduce the layout area. The present disclosure provides a novel contact deployment to fit both wider sheet devices and narrower sheet devices.

According to some embodiments, a semiconductor device includes a first region and a second region disposed adjacent to each other and having a boundary therebetween. The first region includes a first active region, a second active region and a third active region extending in a first direction and having different widths measured along a second direction different from the first direction. The first region includes a first gate electrode, a second gate electrode and a third gate electrode extending in the second direction and disposed across the first active region, the second active region and the third active region respectively. From a top view, the first active region has a first edge and a second edge opposite to each other, the first edge of the first active region is aligned with an edge of the second active region, and the second edge of the first active region is aligned with an edge of the third active region.

According to some embodiments, a semiconductor device includes a first region and a second region disposed adjacent to each other and having a boundary therebetween. The first region includes a first active region, a second active region and a third active region extending in a first direction. The first region includes a first gate electrode, a second gate electrode and a third gate electrode extending in a second direction and disposed across the first active region, the second active region and the third active region respectively. The first region includes a first metal contact, a second metal contact and a third metal contact extending in the second direction and across the first active region, the second active region and the third active region respectively. The first region includes a first metal line, a second metal line and a third metal line extending in the second direction, disposed across the first gate electrode, the second gate electrode and the third gate electrode respectively, and electrically connected to the first metal contact, the second metal contact and the third metal contact respectively. The first active region, the second active region and the third active region have a first width, a second width and a third width measured along the second direction respectively. The first metal contact, the second metal contact and the third metal contact have a first length, a second length and a third length measured along the second direction respectively. The first width is greater than the second width or the third width, the first length is greater than the third length, and the third length is greater than the second length.

According to some embodiments, a semiconductor device includes a first region and a second region disposed adjacent to each other and having a boundary therebetween. The first region includes at least three active regions extending in a first direction and having different channel widths, at least three gate electrodes extending in a second direction and disposed across the active regions respectively, at least three metal contacts extending in the second direction and across the active regions respectively, and at least three metal lines extending in the first direction and across the gate electrodes respectively. A contact length of one of the metal contacts farther away from the boundary between the first and second regions is shorter than a contact length of another of the metal contacts closer to the boundary between the first and second regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first region and a second region disposed adjacent to each other and having a boundary therebetween,
wherein the first region comprises:
a first active region, a second active region and a third active region extending in a first direction and having different widths measured along a second direction different from the first direction; and
a first gate electrode, a second gate electrode and a third gate electrode extending in the second direction and disposed across the first active region, the second active region and the third active region respectively,
wherein from a top view, the first active region has a first edge and a second edge opposite to each other, the first edge of the first active region is aligned with an edge of the second active region, and the second edge of the first active region is aligned with an edge of the third active region.

2. The semiconductor device of claim 1, wherein the second region comprises:
a fourth active region, a fifth active region and a sixth active region extending in the first direction and having different widths; and
a fourth gate electrode, a fifth gate electrode and a sixth gate electrode extending in the second direction and disposed across the fourth active region, the fifth active region and the sixth active region respectively.

3. The semiconductor device of claim 2, wherein the fourth active region has a third edge and a fourth edge opposite to each other, the third edge of the fourth active region is aligned with an edge of the fifth active region, and the fourth edge of the fourth active region is aligned with an edge of the sixth active region.

4. The semiconductor device of claim 3, wherein from a top view, the first active region, the second active region and the third active region are arranged symmetrically to the fourth active region, the fifth active region and the sixth active region with respect to the boundary between the first region and the second region.

5. The semiconductor device of claim 3, wherein from a top view, the first active region, the second active region and the third active region are arranged asymmetrically to the fourth active region, the fifth active region and the sixth active region with respect to the boundary between the first region and the second region.

6. The semiconductor device of claim 1, wherein the first gate electrode, the second gate electrode and the third gate electrode have the same width.

7. The semiconductor device of claim 1, further comprising:
dielectric walls extending in the second direction, and configured to separate the first active region, the second active region and the third active region from each other.

8. The semiconductor device of claim 5, further comprising:
spacers extending in the second direction on sidewalls of each of the first gate electrode, the second gate electrode, the third gate electrode and the dielectric walls.

9. The semiconductor device of claim 1, further comprising:
a first metal contact, a second metal contact and a third metal contact extending in the second direction and adjacent to the first gate electrode, the second gate electrode and the third gate electrode respectively; and
a first metal line, a second metal line and a third metal line extending in the first direction, and disposed across the first gate electrode, the second gate electrode and the third gate electrode respectively.

10. The semiconductor device of claim 1, wherein the first nanosheets are vertically stacked in the first active region, second nanosheets are vertically stacked in the second active region and third nanosheets are vertically stacked in the third active region, and the first nanosheets are wider than the second nanosheets or the third nanosheets.

11. A semiconductor device, comprising:
a first region and a second region disposed adjacent to each other and having a boundary therebetween, wherein the first region comprises:
a first active region, a second active region and a third active region extending in a first direction;
a first gate electrode, a second gate electrode and a third gate electrode extending in a second direction and disposed across the first active region, the second active region and the third active region respectively; and
a first metal contact, a second metal contact and a third metal contact extending in the second direction and across the first active region, the second active region and the third active region respectively,
wherein the first active region, the second active region and the third active region have a first width, a second width and a third width measured along the second direction respectively,
wherein the first metal contact, the second metal contact and the third metal contact have a first length, a second length and a third length measured along the second direction respectively, and
wherein the first width is greater than the second width or the third width, the first length is greater than the third length, and the third length is greater than the second length.

12. The semiconductor device of claim 11, wherein from a top view, the first active region has a first edge and a second edge opposite to each other, the first edge of the first active region is aligned with an edge of the second active region, and the second edge of the first active region is aligned with an edge of the third active region.

13. The semiconductor device of claim 11, wherein the second region comprises:
a fourth active region, a fifth active region and a sixth active region having different widths and extending in the first direction; and
a fourth gate electrode, a fifth gate electrode and a sixth gate electrode extending in the second direction and disposed across the fourth active region, the fifth active region and the sixth active region respectively.

14. The semiconductor device of claim 13, wherein from a top view, the fourth active region has a third edge and a fourth edge opposite to each other, the third edge of the fourth active region is aligned with an edge of the fifth active region, and the fourth edge of the fourth active region is aligned with an edge of the sixth active region.

15. The semiconductor device of claim 11, wherein the first nanosheets are vertically stacked in the first active region, second nanosheets are vertically stacked in the second active region and third nanosheets are vertically stacked in the third active region, and the first nanosheets are wider than the second nanosheets or the third nanosheets.

16. The semiconductor device of claim 11, further comprising:
dielectric walls extending in the second direction, and configured to separate the first active region, the second active region and the third active region from each other.

17. The semiconductor device of claim 16, further comprising:
spacers extending in the second direction on the sidewalls of the first gate electrode, the second gate electrode, the third gate electrode and the dielectric walls.

18. A semiconductor device, comprising:
a first region and a second region disposed adjacent to each other and having a boundary therebetween, wherein the first region comprises:
at least three active regions extending in a first direction and having different channel widths;
at least three gate electrodes extending in a second direction and disposed across the active regions respectively;
at least three metal contacts extending in the second direction and across the active regions respectively; and
at least three metal lines extending in the first direction and across the gate electrodes respectively,
wherein a contact length of one of the metal contacts farther away from the boundary between the first and second regions is shorter than a contact length of another of the metal contacts closer to the boundary between the first and second regions.

19. The semiconductor device of claim 18, wherein from a top view, the fourth active region has a third edge and a fourth edge opposite to each other, the third edge of the fourth active region is aligned with an edge of the fifth active region, and the fourth edge of the fourth active region is aligned with an edge of the sixth active region.

20. The semiconductor device of claim 18, wherein the first nanosheets are vertically stacked in the first active region, second nanosheets are vertically stacked in the second active region and third nanosheets are vertically stacked in the third active region, and the first nanosheets are wider than the second nanosheets or the third nanosheets.
